(19) United States
(12) Patent Application Publication
(10) Pub. No.: US 2011/0198719 A1
(43) Pub. Date: Aug. 18, 2011

(54) ELECTRONIC DEVICE COMPRISING A PLURALITY OF ELECTRONIC COMPONENTS LAID DOWN ON A SUBSTRATE AND ASSOCIATED INFRARED SENSOR

(75) Inventor: Pierre Burgaud, Guichen (FR)

(73) Assignee: ETAT FRANCAIS REPRESENTE PAR LE DELEGUE GENERAL POUR L'ARMEMENT, Arcueil (FR)

(21) Appl. No.: 12/994,597

(22) PCT Filed: Jul. 6, 2009
(86) PCT No.: PCT/FR09/00832

§ 371 Date: Nov. 24, 2010

(30) Foreign Application Priority Data
Jul. 4, 2008 (FR) 0803798

(51) Int. Cl. H01L 31/02; H01L 23/488; H01L 29/22; H01L 29/20

(52) U.S. Cl. 257/459; 257/779; 257/614; 257/615; 257/E31.113; 257/E23.023; 257/E29.094; 257/E29.089

(57) ABSTRACT

An electronic device having a plurality of electronic components placed on a substrate, each component being constituted by a portion of a layer of active material joined mechanically to the substrate by an electrically conductive joining element pertinent to it, the layer of active material having at least one trench delimiting, at least in part, groups of electronic components each having at least two components and forming successive strips, two successive strips having a common boundary.

### BACKGROUND

The present invention relates to a system of components to be hybridized, adapted to a melt hybridization technique using solder beads of the kind known by the term “flip-chip.”

The invention is applicable especially in the fields of electronics and optics, for interconnecting components made of different materials.

As an example, the invention can be used especially for interconnecting silicon components with components such as HgCdTe, AsGa, or InSb.

For purposes of the present invention a “component” is understood as an electronic component such as an electronic chip, an electronic or optoelectronic circuit support, as well as a mechanical component such as a cover or a sensor of physical variables.

The invention can be used in particular for the manufacture of infrared detectors, the manufacture of vertical-cavity lasers, or for placing a matrix of reading photodiodes onto a silicon reading circuit.

A detector of this kind comprising a substrate, a layer of active material, and means for mechanically joining said layer to the substrate, is known. The substrate can be made e.g. of silicon and can be a constituent of a reading circuit, while the active material can be made of HgCdTe and the mechanical joining means can be constituted by solder (bumps). The distribution of these solder bumps allows definition of a distribution of components (also called “pixels”).

A distinction is made between two principal techniques for hybridizing components using solder bumps.

The flip chip interconnect technology technique is widely known at present. It utilizes beads produced from a meltable material, for example a tin-lead alloy, tin-indium, or even made of pure indium.

Succinctly, the flip chip interconnect technique comprises:
depositing bumps of solder material onto pads produced on one of the components, said pads being constituted from a material that can be wetted by the material constituting the solder bumps;
then equipping the other component to be hybridized with pads likewise constituted from a material that can be wetted by the material constituting the solder bumps, said pads being set up substantially directly above the pads of said first component when said second component is placed onto the first;
then, by increasing the temperature until reaching a temperature above the melting temperature of the constituent material of the bumps, achieving melting thereof until the desired result is obtained, i.e. hybridizing the second component onto the first component, said bumps creating a mechanical and/or electrical interconnect between the pads of each component.

For components of relatively small dimensions, the mutual positioning accuracy of said components upon placement of the upper component onto the lower component is not very critical. This is because surface tension phenomena acting on the hybridization bumps during the melting operation induce automatic alignment of said components. In addition, these same surface tension phenomena allow at the very least partial absorption of the thermal expansion phenomena that affect the two components having different coefficients of thermal expansion and that are expressed as relative displacement of the pads of one component with respect to the other.

For components of larger dimensions, one known technical solution, associated with the problem of differential expansion of the components, consists in compensating for the expansion phenomena by acting directly at the component design level.

The document FR 2 748 849 thus proposes to displace the wettable surfaces of the component to be hybridized in linearly homothetic fashion so that at the hybridization temperature, said wettable surfaces are once again located, in a non-offset fashion, substantially directly opposite the wettable surfaces or pads of the other component, thereby absorbing the differential expansion.

This type of matrix has a low technological yield, however. In addition, it can be used only for matrix dimensions greater than 100×1000, and has a limitation in terms of operation reliability in terms of the number of cooling and return-to-ambient cycles during operation, which cause shear stresses at the bumps. Solutions at the image processing software level allow correction of certain isolated defects that can appear during the life cycle of the imager, but there is no solution for larger malfunction areas, resulting in a complete loss of information on areas of the display screen.

To eliminate these drawbacks, application FR2903811 is known; it describes an electronic device comprising a plurality of electronic components placed on a substrate, each component being mechanically joined to the substrate by means of a joining element, and wherein each component is furthermore electrically connected to at least one conductor having an elasticity capable of maintaining the integrity of the electrical connection to an adjacent component despite a relative displacement between components. Subdivision of the component thus allows the elongation or compression imposed by the difference in thermal coefficients to be interrupted. During the manufacture of such matrices, however, production (by etching) of a trench for mechanical separation of the components interrupts the electrical connection provided by the substrate, and after etching an electrically conductive deposit must be effected to ensure connection between the separated elements. This additional step is acknowledged as a complication of the process. In addition, this bridging film must also possess sufficient elasticity to maintain the electrical connection despite a relative displacement between components, and moreover in a stressful environment, namely around the temperature of liquid nitrogen for infrared imagers using HgCdTe components.

Independently, with regard to the present flip-chip (FC) hybridization method for IR imagers presently adhered to by the profession, which takes advantage of a reduction in sensor thickness by thinning an underfill material—which ensures, inter alia, good mechanical adhesion of the indium bumps during the sensor thinning operation after hybridization but likewise during the imager life cycle—additional steps of lithography and deposition of a specific metallic film are thus necessary either before or after hybridization. This deposition is effected by providing metal bridges on the substrate side opposite the indium bump interface, but because of the implementation of the proposed method, also eliminates any possibility of utilizing an underfill.

### SUMMARY

The object of the invention is to remedy the aforementioned disadvantages, in particular by allowing the production of arrays of large dimensions (1K×1K, 2K×2K or even greater) which exhibit a high level of operational reliability and do not require the implementation of metal bridges after etching, and allow the elimination of sensor thinning after hybridization.

This object is achieved by way of an electronic device comprising a plurality of electronic components placed on a substrate, each component being constituted by a portion of a layer of active material joined mechanically to the substrate by means of an electrically conductive joining element pertinent to it, the layer of active material comprising at least one trench, wherein said at least one trench delimits, at least in part, groups of electronic components each comprising at least two components, said groups of electronic components forming successive strips, two successive strips comprising a common boundary.

“Successive strips comprising a common boundary” are to be understood as follows:
a first strip has a common boundary with a second strip,
said second strip has a common boundary with a third strip,
said third strip has a common boundary with a fourth strip, etc. . .

According to a particular characteristic, at least one of the trenches forms a broken line.

According to another particular characteristic, the entirety of said successive strips forms only one global, non-rectilinear strip.

According to a particular characteristic that requires the use, for polarization of said layer, of only one supplementary electrical connection common to all the components, the layer of active material is monoblock.

The layer of active material is thus in a single piece and is made up of a series of strips, each strip having a common boundary with at least one other strip.

According to another characteristic, each component is integral, at the level of the layer of active material, with at least one other component.

According to an additional characteristic, a device according to the present invention comprises successive rectilinear trenches forming a spiral.

According to another characteristic, the layer of active material is selected from HgCdTe, InSb, and AsGa.

According to an additional characteristic, the substrate is made of silicon, gallium arsenide, or amorphous or crystalline alumina, and can be made up of multiple juxtaposed blocks, optionally made of different materials.

According to a characteristic of the invention, the electrically conductive joining elements are made of meltable material, for example indium or a tin-lead, tin-silver-copper, or tin-indium alloy.

According to another characteristic, a device according to the present invention comprises polarization means connected to each of the components on the one hand via said electrically conductive joining elements and on the other hand by way of a single connection common to all the components.

According to another characteristic, the layer of active material comprises an upper surface covered by an electrically conductive film, or is doped with impurities rendering it electrically conductive.

The invention also relates to an infrared sensor comprising a device according to the present invention.

### BRIEF DESCRIPTION OF THE DRAWINGS

Other advantages and characteristics will become evident in the description of an embodiment of the invention referring to the attached Figures, in which:

FIGS. 2a, 2b, and 2c depict a simplified layout of a first embodiment of an electronic device according to the present invention,

FIGS. 3a, 3b, and 3c depict a simplified layout of a second embodiment of an electronic device according to the present invention,

FIGS. 4 and 5 show two other variant embodiments of arrangements of trenches produced in the layer of active material of a device according to the present invention,

FIGS. 6a to 6e show various phases of a method for producing, by photolithography, trenches in the layer of active material of a device according to the present invention.

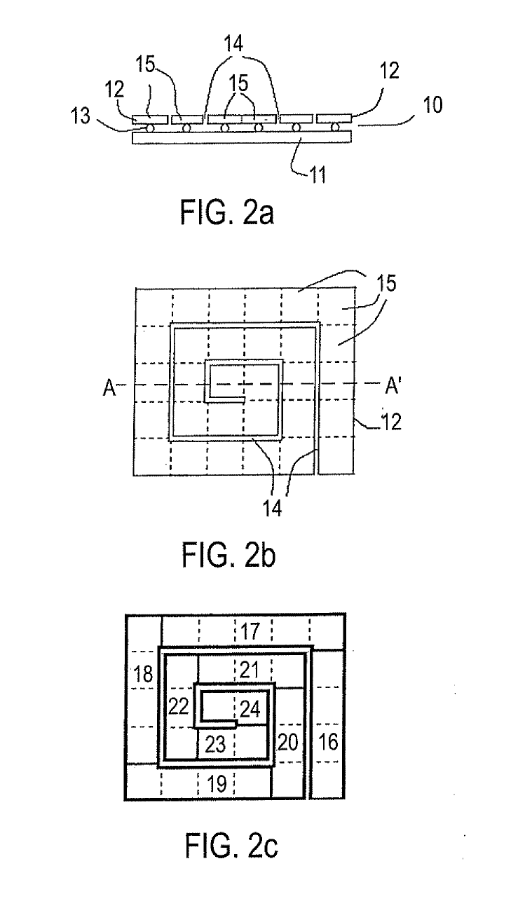

FIGS. 2a, 2b, and 2c depict a simplified layout of a first embodiment of an electronic device according to the present invention.

### DETAILED DESCRIPTION OF EMBODIMENTS

This electronic device 10 comprises a substrate 11, a layer 12 of active material, and means 13 for mechanically joining said layer 12 to substrate 11. The substrate can be made, for example, of silicon and can be a constituent of a readout circuit, while the active material can be an alloy of cadmium (Cd), mercury (Hg), and tellurium (Te), such as HgCdTe, suitable for detecting infrared radiation, and mechanical joining means 13 can be constituted by solder bumps. The distribution of these solder bumps allows definition of a distribution of components 15 that are also called “pixels.” As shown in FIG. 2b, a simplified matrix of 5×6 components is depicted, each component being delimited by dashed lines and being constituted by a portion of said layer 12 of active material, said portion being linked to substrate 11 by a solder bump 13. Said solder bump constitutes not only a mechanical join to the substrate that ensures mechanical cohesion of the assemblage, but moreover an electrical connection. It can be produced in the context of a “flip-chip” assembly method.

This mechanical join can also, for example, be constituted by a pad made of electrically conductive polymer.

Layer 12 of active material furthermore comprises a trench 14 forming a broken line similar to a spiral, such that each component is in contact with at least one other component at the level of layer 12 of active material, said layer 12 being monoblock. As shown in FIG. 2c, trench 14 delimits, at least in part, groups of electronic components 16, 20; 17, 21; 18, 22; 19, 23; 20, 23, 24; 21, 24; 22, 24; 23, 24 that each comprise at least two components and occur in the form of successive strips 16, 17, 18, 19, 20, 21, 22, 23, two successive strips comprising a common boundary 25. The contours of these groups or strips have been marked on said FIG. 2c with a heavy line. Layer 12 of active material is thus monoblock, while trench 14 delimits groups of electronic components forming successive strips 16, 17, 18, 19, 20, 21, 22, 23, two successive strips having a common boundary 25 and the entirety of said successive strips forming only one global, non-rectilinear strip.

Trench 14 allows free expansion or compression of layer 12 of active material, thus preventing it from breaking; and since layer 12 of material is monoblock, the polarization of the electronic components can be achieved on the one hand via electrically conductive mechanical joining means constituting a first electrical connection specific to each of the electronic components, and on the other hand by way of a second electrical connection applied to layer 12 of active material, said second connection being unique for the entire layer 12 of active material.

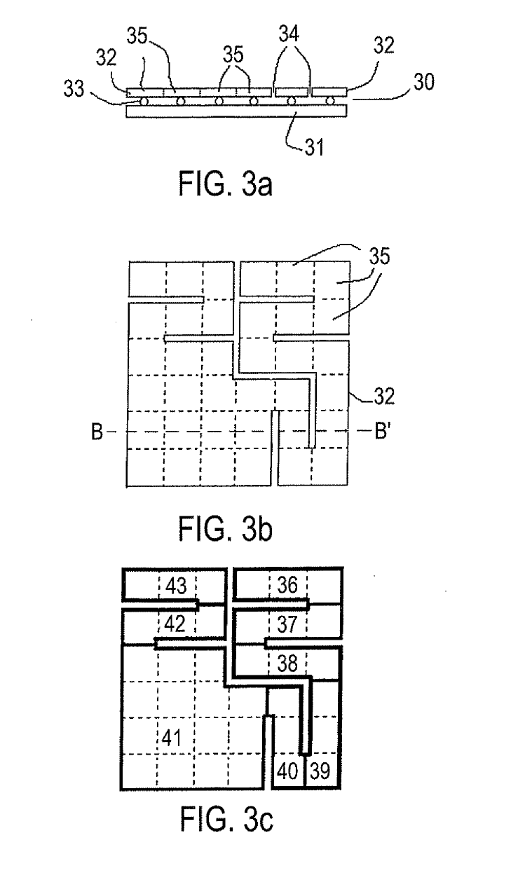

FIG. 3 shows a second exemplifying embodiment of an electronic device according to the present invention.

This electronic device 30 comprises a substrate 31, a layer 32 of active material, and means 33 for mechanically joining said layer 32 to substrate 31. The substrate can be made, for example, of silicon and can be a constituent of a readout circuit, while the active material can be an alloy of cadmium (Cd), mercury (Hg), and tellurium (Te), such as HgCdTe, suitable for detecting infrared radiation, and mechanical joining means 33 can be constituted by solder bumps. The distribution of these solder bumps allows definition of a distribution of components 35 that are also called “pixels.” As shown in FIG. 3b, a simplified array of 6×6 components is depicted, each component being delimited by dashed lines and being constituted by a portion of said layer 32 of active material, said portion being linked to substrate 31 by a solder bump 33. Said solder bump constitutes not only a mechanical join to the substrate that ensures mechanical cohesion of the assemblage, but moreover an electrical connection. It can be produced in the context of a “flip-chip” assembly method.

Layer 32 of active material furthermore comprises a trench 34, such that each component is in contact with at least one other component at the level of layer 32 of active material, said layer 32 being monoblock. As shown in FIG. 3c, trenches 34 delimit at least in part groups of electronic components 36, 37; 37, 38; 39, 40; 40, 41; . . . each comprising at least two components and forming successive strips 36, 37, 38, 39, 40, 41, 42, 43, two successive strips comprising a common boundary 44. The contours of these strips have been marked on said FIG. 3c with a heavy line.

Layer 32 of active material is thus monoblock, while trenches 34 delimit groups of electronic components 36, 37, 38, 39, 40, 41, 42, 43.

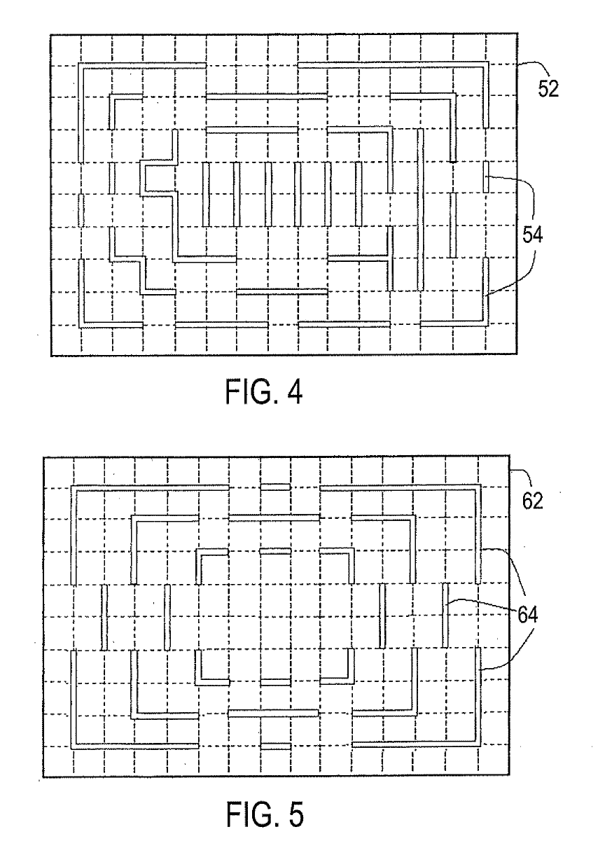

FIGS. 4 and 5 show two other variant implementations of arrangements of trenches 54, 64 produced in layer 52, 62 of active material. These trenches 54, 64 divide the layers into strips of electrical components the number of which is variable, each of said strips having a common boundary with at least one strip that is juxtaposed with it.

A method for manufacturing a device according to the present invention can be as follows: Indium bumps 74 are deposited in regular fashion on a silicon substrate 71. Diodes 76 are secured on the lower surface of a layer 72 of active material, and indium beads are deposited between the substrate and each diode. Indium beads 74 are then melted by heating, and solidification thereof after heating ensures a mechanical join between substrate 71 and layer 72 of active material.

The formation of trenches in the layer of active material can be effected using a radiation-based subtractive technique, for example using a photolithography method.

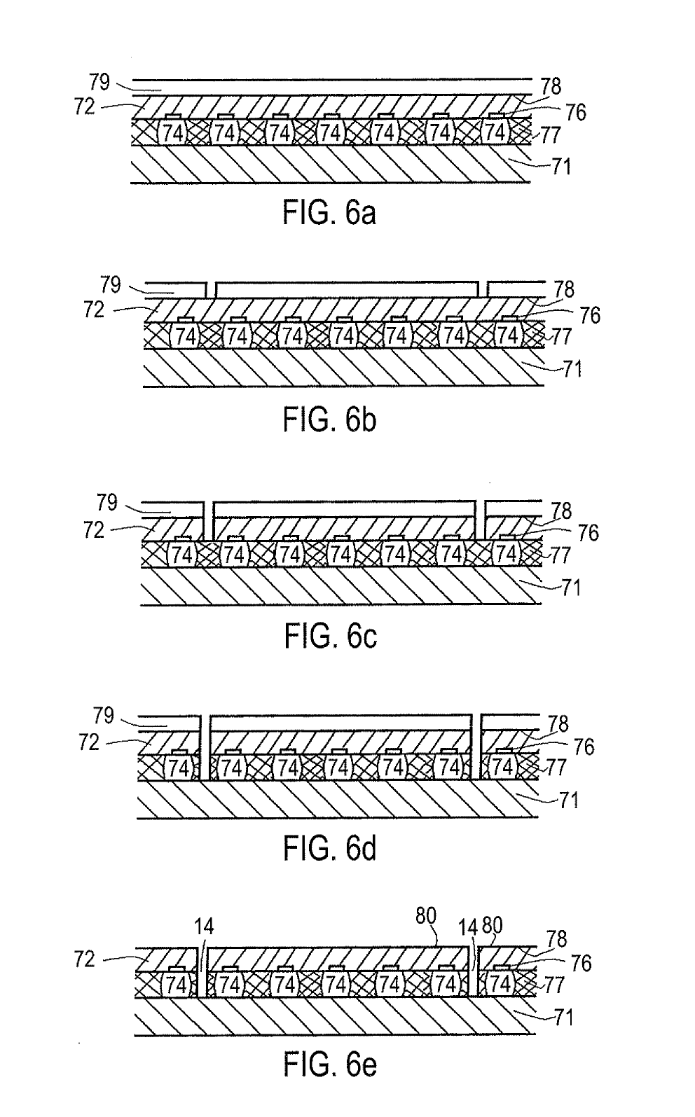

For this, as illustrated in FIGS. 6a to 6e, exposed surface 78 of layer 72 of active material is covered with a photosensitive resin 79, then ultraviolet (UV) radiation is applied thereonto through a subtractive mask defining those portions of the layer of material to be eliminated in order to form functional patterns. In response to the UV radiation, the exposed positive resin portion undergoes a chemical transformation that allows it to be eliminated by a development process using an alkaline solution. Once development is complete, those portions of layer 72 of active material that must be eliminated are thus flush and are eliminated, simultaneously with the corresponding layer of filling material 77, by chemical etching. At the same time, the unexposed resin has not been eliminated by development and thus protects the pattern material from etching. Once this unexposed resin portion has been eliminated by a chemical bath, the desired trenches then appear at the surface of electronic components 78, as shown in FIG. 6e. In this embodiment, the two trenches 14 are separated by five pixels.

Numerous modifications can furthermore be made to the variant embodiments described above. For example, the distribution of trenches depends especially on the environmental conditions in which the device is intended to operate. If there is little fluctuation in environmental conditions, the number of trenches could be reduced to one or two, whereas if said conditions vary greatly, numerous trenches could be dug, for example as in the case of FIG. 4, thus allowing the layer of active material, and hence the electronic components, to be divided into strips capable of deforming because the trenches are present, said deformations being below the elastic limit of the layer.

In addition, the layer of active material can be made of a material other than HgCdTe, for example InSb or AsGa.

The bump of solderable material can moreover also, for example, be constituted from a tin-lead, tin-silver-copper, or tin-indium alloy.

Moreover, at least one of the substrates can be made, for example, of gallium arsenide (AsGa) or amorphous or crystalline alumina (Al₂O₃), and/or made up of multiple juxtaposed blocks optionally made of different materials.

In addition, if the active material layer is not electrically conductive, an electrically conductive (e.g. metallic) film can be deposited onto its upper surface 80, a requirement being that said film must be transparent to the operating wavelength of the system; or it can be doped at least in part at the level of the upper surface, with impurities capable of rendering it electrically conductive. This film or doping then allows a polarizing voltage then to be applied, again via the joining means, to the layer of active material.

1. An electronic device comprising
a plurality of electronic components placed on a substrate, each component being constituted by a portion of a layer of active material joined mechanically to the substrate by means of an electrically conductive joining element pertinent to it, the layer of active material comprising at least one trench,
wherein said at least one trench delimits, at least in part, groups of electronic components each comprising at least two components and forming successive strips, two successive strips comprising a common boundary.

2. The electronic device according to claim 1, wherein at least one of the trenches forms a broken line.

3. The device according to claim 1, wherein the entirety of said successive strips forms only one global, non-rectilinear strip.

4. The device according to claim 1, wherein the layer of active material is monoblock.

5. The device according to claim 1, wherein each component is integral, by way of its layer of active material, with at least one other component.

6. The device according to claim 1, wherein it comprises a trench forming a spiral.

7. The device according to claim 1, wherein the layer of active material is selected from HgCdTe, InSb, and AsGa.

8. The device according to claim 1, wherein the substrate is made up of multiple juxtaposed blocks.

9. The device according to claim 1, wherein the substrate comprises at least one block made of silicon, of gallium arsenide, and/or of amorphous or crystalline alumina; and/or the electrically conductive joining elements are made of a solderable material.

10. The device according to claim 1, further comprising polarization means connected to each of the components via said electrically conductive joining elements and by way of a single connection common to all the components.

11. The device according to claim 1, wherein the layer of active material comprises an upper surface covered by an electrically conductive film, or is doped with impurities rendering it electrically conductive.

12. An infrared sensor comprising a device according to claim 1.
